(19) United States
(12) Patent Application Publication
(10) Pub. No.: US 2006/0108507 A1
(43) Pub. Date: May 25, 2006

(54) Active pixel sensor and image sensing module

(75) Inventor: Chien-Chang Huang, Hsinchu-Hsien (TW)

Correspondence Address: DARBY & DARBY P.C., P. O. BOX 5257, NEW YORK, NY, 10150-5257, US

(73) Assignee: Pixart Imaging Inc., Hsinchu Hsien (TW)

(21) Appl. No.: 11/073,319

(22) Filed: Mar. 4, 2005

(30) Foreign Application Priority Data
Nov. 22, 2004 (TW) 093135844

(51) Int. Cl. H01L 27/00

(52) U.S. Cl. 250/208.1

(57) ABSTRACT

An active pixel sensor includes a photosensitive element, and first and second transistors. The photosensitive element generates an electrical signal in response to detected light, and updates the electrical signal in response to a reset signal. The first transistor is coupled electrically to the photosensitive element, and amplifies the electrical signal to result in an output signal. The second transistor is coupled electrically to the first transistor, and is responsive to a row select signal for controlling output of the output signal. An image sensing module built from active pixel sensors is also disclosed.

### CROSS-REFERENCE TO RELATED APPLICATION

This application claims priority of Taiwanese application no. 093135844, filed on Nov. 22, 2004.

### BACKGROUND OF THE INVENTION

1. Field of the Invention

The invention relates to a pixel sensor, more particularly to a complementary metal-oxide semiconductor (CMOS) active pixel sensor and to an image sensing module built therefrom.

2. Description of the Related Art

Current image sensing techniques use either charge-coupled devices (CCD) or complementary metal-oxide semiconductors (CMOS). Aside from being found in optical mice, CMOS image sensors are also used in digital cameras, video phones, third generation handsets, etc.

A CMOS image sensor includes a pixel array, which is in the form of a plurality of rows and columns of pixel units. Each pixel unit is either a passive pixel sensor or an active pixel sensor.

FIG. 1 illustrates a conventional passive pixel sensor 8. The pixel sensor 8 includes a photo diode 81 and a transfer gate 82. Because there is only one transistor, the pixel sensor 8 can be referred to as having a 1T-structure. In use, the photo diode 81 is excited by external light rays 7 and generates corresponding photo charges. Turning-on and turning-off of the transfer gate 82 are controlled using a row select signal 801. When the transfer gate 82 is turned on, a column output signal 802 is obtained. The column output signal 802 is then processed using signal amplification and analog-to-digital conversion techniques to result in a corresponding video signal. The aforesaid pixel sensor 8 is disadvantageous in that the magnitude of the sensed signal generated thereby is very small. Furthermore, as the read circuit thereof is susceptible to parasitic capacitance, a relatively large amount of noise is present in the output of the pixel sensor 8. As a consequence, active pixel sensors are preferred over passive pixel sensors.

FIG. 2 illustrates a conventional active image sensing module 9. The image sensing module 9 includes a pixel array 91, a row addressing circuit 92, a column decoder 93, a timing generating circuit 94, and an amplifier 95. The pixel array 91 includes M×N pixel sensors 911. The row addressing circuit 92 provides row select signals 901 and reset signals 902 to the rows of the pixel sensors 911 in the pixel array 91, thereby controlling the output and update of electrical charges that are attributed to received external light rays. The column decoder 93 receives column output signals 903 from the pixel array 91, decodes the same, and provides a decoded output to the amplifier 95 for amplification. The timing generating circuit 94 provides timing control signals to control the generation of the row select signals 901 and the reset signals 902 by the row addressing circuit 92, as well as receipt of the column output signals 903 by the column decoder 93.

FIG. 3 illustrates a conventional active pixel sensor 3 with a 3T-structure. The pixel sensor 3 includes a photo diode (PD₃), a reset transistor (T₃₁), a source follower transistor (T₃₂), and a row select transistor (T₃₃).

In use, the transistor (T₃₁) is turned on upon receipt of a high-level reset signal 301 to clear photo charges that were accumulated by the photo diode (PD₃) during a previous operation. Thereafter, the transistor (T₃₁) is turned off by providing a low-level reset signal 301 thereto. At this time, the photo diode (PD₃) is excited by external light rays 7 to result in the generation of corresponding photo charges. The photo charges are converted into a voltage output and are discharged to result in a drop in the voltage (VA). In view of a shift in voltage drop attributed to the transistor (T₃₂), the transistor (T₃₃) will be turned on upon receipt of a row select signal 302 such that a column output signal 303 is generated. Hence, after reading the column output signal 303, the high-level reset signal 301 is provided once again to the transistor (T₃₁) for updating the charges accumulated by the photo diode (PD₃).

In particular, to turn on the transistor (T₃₁), the high-level reset signal 301 is applied to the gate of the transistor (T₃₁), thereby resulting in a reverse bias voltage for the photo diode (PD₃). As a result, a depletion region is formed in the photo diode (PD₃). The depletion region absorbs photons and generates electrical currents when exposed to light.

During exposure, the transistor (T₃₁) is turned off. In response to the external light rays 7, the photo diode (PD₃) generates electron-hole pairs corresponding to the intensity of the light source. The electron-hole pairs move to two ends of the photo diode (PD₃), thereby resulting in a drop in the reverse bias voltage. Thereafter, when the transistor (T₃₃) is turned on, a terminate_exposure voltage (V2) is obtained from the source thereof. When the transistor (T₃₃) is maintained on, and the transistor (T₃₁) is then turned on, a start_exposure voltage (V1) is obtained from the source of the transistor (T₃₃). The difference between the terminate_exposure voltage (V2) and the start_exposure voltage (V1) corresponds to the actual exposure voltage value.

In the pixel sensor 3, signal updating and reading operations are conducted by resetting the transistor (T₃₁). The transistor (T₃₂) can prevent mutual interference between the column output signal 303 and the voltage (VA). As a result, less noise is encountered when compared to the direct reset operation using the row select signal 801 in the aforementioned passive pixel sensor 8.

FIG. 4 illustrates a conventional active pixel sensor 4 with a 4T-structure. The pixel sensor 4 includes a photo diode (PD₄), a capacitor (C_{f}), a transfer transistor (T₄₁), a reset transistor (T₄₂), a source follower transistor (T₄₃), and a row select transistor (T₄₃). The functions of the transistors (T₄₂, T₄₃, T₄₄) are the same as those of the transistors (T₃₁, T₃₂, T₃₃) of the above-described pixel sensor 3 and will not be described further for the sake of brevity.

Unlike the pixel sensor 3 of FIG. 3, the pixel sensor 4 of FIG. 4 further includes the capacitor (C_{f}) and the transistor (T₄₁). The photo diode (PD₄) is connected to one end of the transistor (T₄₁). The other end of the transistor (T₄₁) is connected to the transistors (T₄₂, T₄₃) and the capacitor (C_{f}). In addition, the photo diode (PD₄) in the pixel sensor 4 is different from the photo diode (PD₃) in the pixel sensor 3. Because of its PNP construction, the photo diode (PD₄) has a voltage-clamping effect. In other words, the start_exposure voltage can be maintained and is not easily susceptible to noise interference. Hence, the pixel sensor 4 has an improved resistance to noise as compared to the pixel sensor 3.

When the pixel sensor 4 is in use, a high logic signal (V_{DD}) is provided to the gate of the transistor (T₄₁), thereby resulting in an appropriate reverse bias voltage for the photo diode (PD₄) so as to form a depletion region in the photo diode (PD₄). In view of the PNP structure of the photo diode (PD₄), the depletion region increases in size with the increase in voltage. A voltage-clamping effect is achieved when the depletion region occupies the entire N-type region. Thereafter, the depletion region absorbs photons and accumulates electrical charges when exposed to light.

To calculate the exposure amount of the pixel sensor 4, the transistors (T₄₁, T₄₂) are first turned on such that the photo diode (PD₄) is clamped to a fixed voltage level. Then, the transistor (T₄₁) is turned off, and the photo diode (PD₄) begins exposure to the external light rays 7. To read data, the transistor (T₄₂) is turned on, and the capacitor (C_{f}) is charged to a fixed starting level (V_{B}′), which can be read through the column output line 403. Thereafter, the transistor (T₄₁) is turned on. Due to the deep charge well design of the photo diode (PD₄), charges are transferred through the transistor (T₄₁) to the capacitor (C_{f}) such that the capacitor (C_{f}) accumulates a voltage drop. As a result, a new voltage level (V_{B}″) is obtained, and the exposure voltage value is the difference V_{B}′-V_{B}″. It is therefore apparent that through the input of the reset signal 401 to the transistor (T₄₂), and the voltage level shift attributed to the transistor (T₄₃), when the transistor (T₄₄) is turned on via the row select signal 402, a column output signal can be read from the pixel sensor 4 at the column output line 403. To read new data, the reset signal 401 is once again inputted to enable updating of charges.

However, the conventional active pixel sensors 3, 4 suffer from the following drawbacks:

1. In the pixel sensor 3 with the 3T structure, the photo diode (PD₃) is connected to the source of the transistor (T₃₁), and the reverse bias voltage is reset through the transistor (T₃₁). Hence, when either the transistor (T₃₁) or the photo diode (PD₃) experiences a current leakage condition, the voltage levels of the start_exposure voltage (V1) and the terminate_exposure voltage (V2) are affected adversely. In addition, the body effect attributed to the reset transistor (T₃₁) will result in a drop in the reverse bias voltage and in attenuation of the barrier voltage. As a result, the start_exposure voltage (V1) is lowered, which will reduce the image dynamic range correspondingly, thereby affecting adversely the image quality.

2. In the pixel sensor 4 with the 4T structure, the transistor (T₄₁) is used to isolate the photo diode (PD₄) from the source of the reset transistor (T₄₂) to minimize leakage current. However, since four transistors are needed, the aperture ratio will be lower. This is because, in consideration of the unit area of the pixel sensor 4, a larger number of transistors will result in a larger proportion of the total area occupied thereby. This leads to a drop in the proportion of the light transmissible area, and in a corresponding drop in the overall light transmissible area of the pixel array.

3. Transistors are characterized by their susceptibility to KTC noise, which is difficult to eliminate.

4. When the photo diode is exposed to light, electron-hole pairs are separated at the depletion region at the PN junction of the photo diode to generate photo current. Different wavelengths of light will be absorbed at different depths of the PN junction. For example, light with shorter wavelength will be absorbed near the surface of the depletion region, while light with longer wavelength will be absorbed deeper within the depletion region. Since the depletion region of the PN junction is normally present deep in the photo diode, the detecting sensitivity of conventional pixel sensors for light with shorter wavelength, such as blue light, is inferior to that of light with longer wavelength, such as red light.

### SUMMARY OF THE INVENTION

Therefore, the main object of the present invention is to provide an active pixel sensor that can overcome at least one of the aforesaid drawbacks of the prior art.

Another object of the present invention is to provide an image sensing module that is built from the active pixel sensors of this invention.

According to one aspect of the invention, an active pixel sensor comprises: a photosensitive element for generating an electrical signal in response to detected light and for updating the electrical signal in response to a reset signal; a first transistor, coupled electrically to the photosensitive element, for amplifying the electrical signal to result in an output signal; and a second transistor coupled electrically to the first transistor and responsive to a row select signal for controlling output of the output signal.

According to another aspect of the invention, an image sensing module comprises:

a plurality of active pixel sensors, each of which includes a photosensitive element, a first transistor, and a second transistor,
the photosensitive element being capable of generating an electrical signal in response to detected light, and updating the electrical signal in response to a reset signal,
the first transistor being coupled electrically to the photosensitive element and amplifying the electrical signal to result in an output signal,
the second transistor being coupled electrically to the first transistor and being responsive to a row select signal for controlling output of the output signal,
the active pixel sensors being arranged in a rectangular array;

a plurality of reset lines, each of which is coupled to and shared by the active pixel sensors in a respective same row of the rectangular array for transmitting the reset signal to the active pixel sensors in the respective same row of the rectangular array;

a plurality of row lines, each of which is coupled to and shared by the active pixel sensors in a respective same row of the rectangular array for transmitting the row select signal to the second transistors of the active pixel sensors in the respective same row of the rectangular array; and

a plurality of column lines, each of which is coupled to and shared by the active pixel sensors in a respective same column of the rectangular array for transmission of the output signals from the second transistors of the active pixel sensors in the respective same column of the rectangular array.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic circuit diagram of a conventional passive pixel sensor;

FIG. 2 is a schematic block diagram of a conventional active image sensing module;

FIG. 3 is a schematic circuit diagram of a conventional active pixel sensor with a 3T structure;

FIG. 4 is a schematic circuit diagram of another conventional active pixel sensor, which has a 4T structure;

FIG. 5 is a schematic circuit diagram of the first preferred embodiment of an active pixel sensor according to this invention;

FIG. 6 illustrates a photosensitive element and a reset diode of the first preferred embodiment in greater detail;

FIG. 7 illustrates an image sensing module according to the first preferred embodiment of this invention;

FIG. 8 is a schematic circuit diagram of the second preferred embodiment of an active pixel sensor according to this invention; and

FIG. 9 illustrates a photosensitive element of the second preferred embodiment in greater detail.

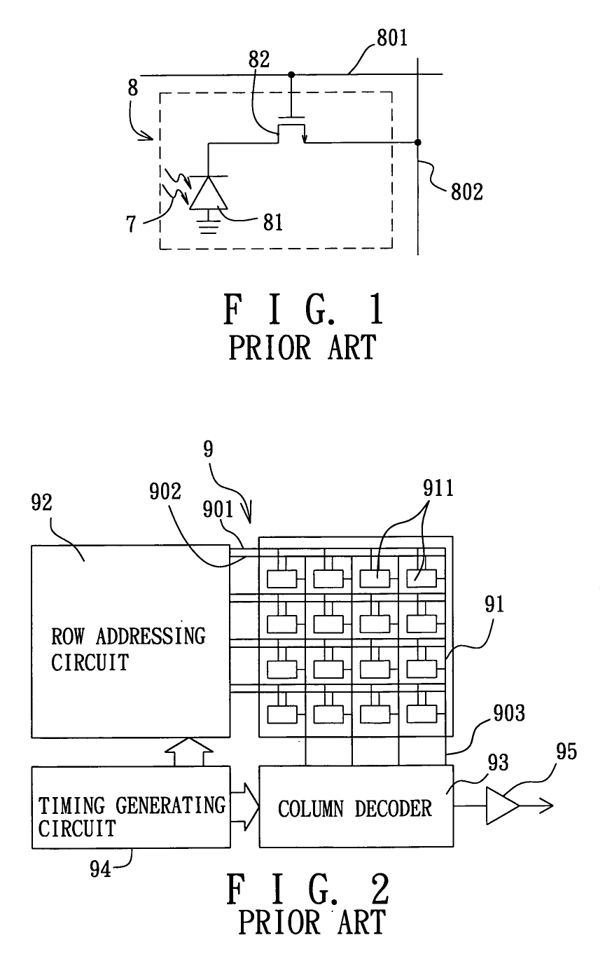

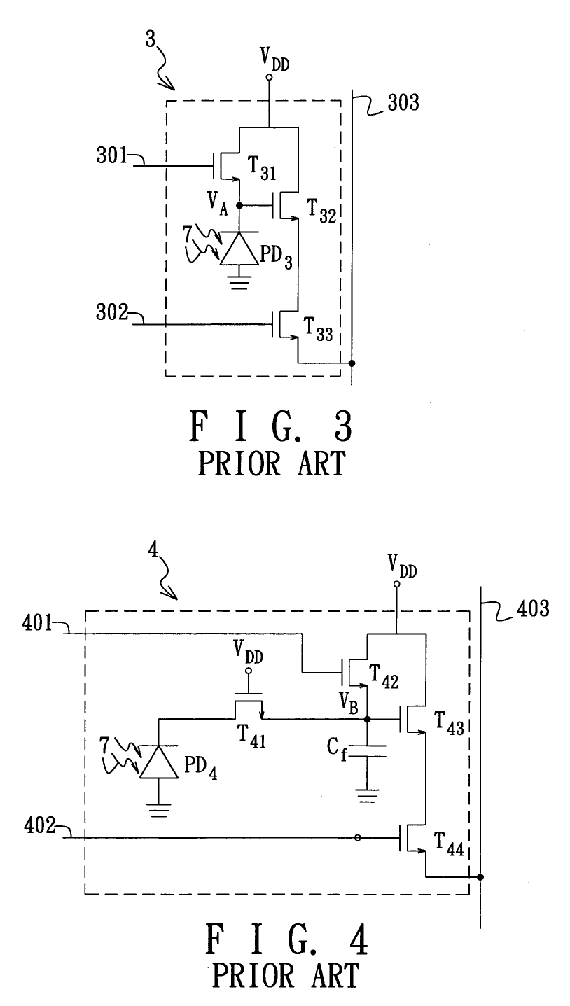

### DETAILED DESCRIPTION OF THE PREFERRED EMBODIMENTS

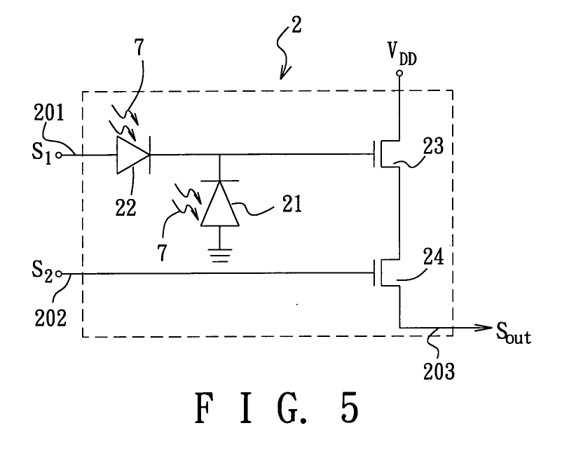

Referring to FIG. 5, the first preferred embodiment of an active pixel sensor 2 according to the present invention is shown to comprise a photosensitive element 21, a reset diode 22, a first transistor 23, and a second transistor 24.

In this embodiment, the photosensitive element 21 and the reset diode 22 are photo diodes. Hence, during an exposure period, external light rays 7 will be converted into electrical signals. The photosensitive element 21 and the reset diode 22 are connected to each other. The start and end of each exposure period are controlled by the magnitude of the voltage level of a reset signal (S₁) at a reset line 201. The first transistor 23 is used to amplify the electrical signals and to convert the same into an output signal. In this embodiment, the first transistor 23 is a source follower having characteristics of large input impedance, small output impedance, large current gain, and a voltage gain that is approximately equal to 1. The first transistor 23 is implemented as an NMOS transistor having a drain that receives a high-level voltage (V_{DD}), a gate that is coupled to the photosensitive element 21 and the reset diode 22, and a source that is coupled to the second transistor 24.

The second transistor 24 is responsive to a row select signal (S₂) at a row line 202 so as to control supply of the output signal (Sₒᵤₜ) at a corresponding column line 203. In this embodiment, the second transistor 24 is implemented as an NMOS transistor having a drain coupled to the source of the first transistor 23, a gate that receives the row select signal (S₂), and a drain from which the output signal (Sₒᵤₜ) is obtained.

In use, a high-level reset signal (S₁) is provided to the reset diode 22 so as to result in a reverse bias voltage for the photosensitive element 21. As a consequence, a depletion region will be formed at the PN junction of the photosensitive element 21. When exposed to light, the depletion region absorbs photons and generates electrical current. Since the reset diode 22 is a photo diode, it also generates electrical current when exposed to light. Hence, a start_exposure voltage (V1) is detected at the corresponding column line 203.

Thereafter, exposure of the photosensitive element 21 and the reset diode 22 begins with the supply of a low-level reset signal (S₁). Due to the exposure to external light rays 7, electrical charges that are proportional to the intensity of the light source are generated accordingly. When the second transistor 24 is turned on due to the application of a high-level row select signal (S₂) at the gate of the second transistor 24, the electrical charges are amplified by the first transistor 23, and a terminate_exposure voltage (V2) is obtained at the corresponding column line 203 accordingly. An exposure period is completed by calculating the voltage difference between the start_exposure and terminate_exposure voltages (V1, V2).

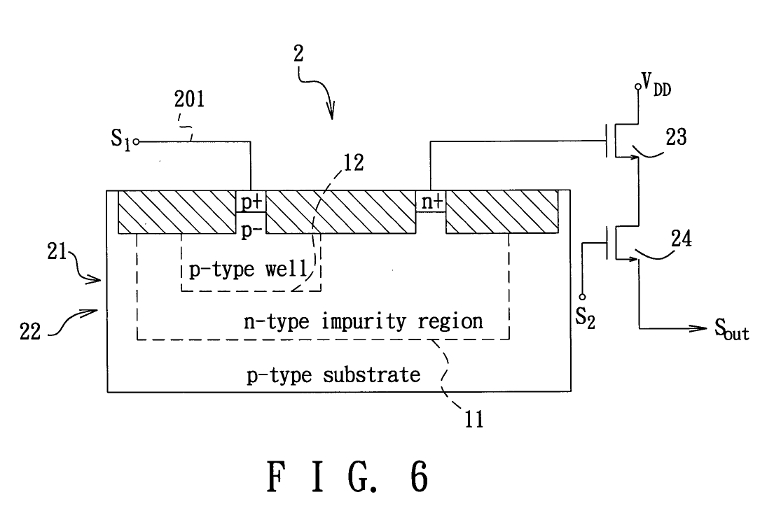

As shown in FIG. 6, to form the reset diode 22, a p-type well 12 is provided in an n-type impurity region 11 of the photosensitive element 21. As a result, a depletion region is formed to permit absorption of more photons, and to augment light sensing ability of the photosensitive element 21. In addition, the start_exposure voltage (V1) is increased, thereby increasing the image dynamic range for improving imaging sensitivity.

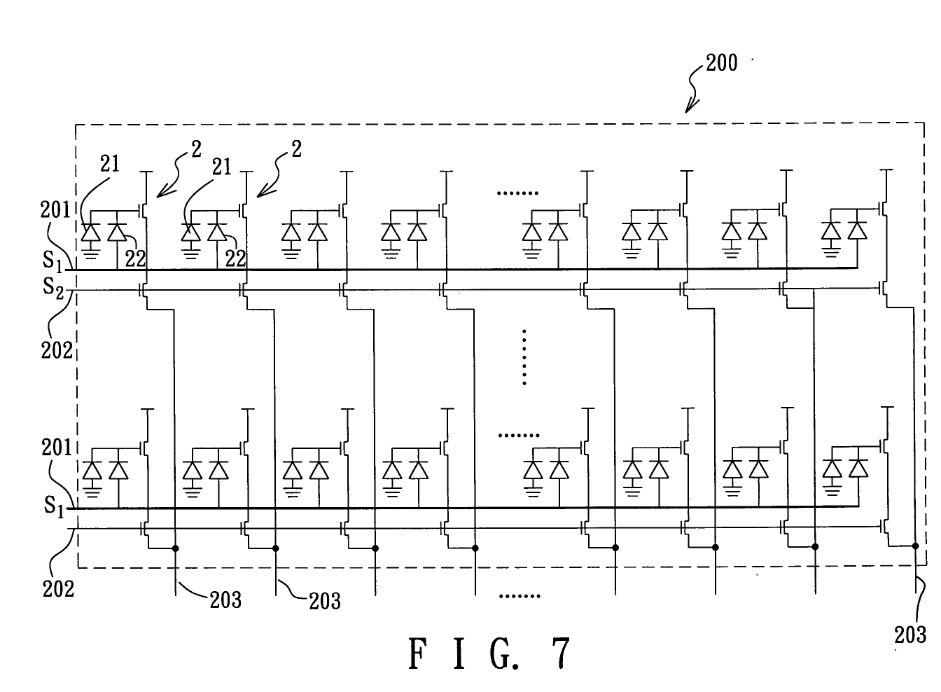

FIG. 7 illustrates an image sensing module 200 that includes a plurality of the pixel sensors 2. The pixel sensors 2 are arranged into a rectangular array. The pixel sensors 2 in a same row share a common reset line 201. The pixel sensors 2 in the same row further share a common row line 202 coupled to the gates of the second transistors 24. Moreover, the pixel sensors 2 in a same column share a common column line 203 for transmission of the output signal (Sₒᵤₜ). For additional information on the control process for the image sensing module 200, one may refer to the known arrangement shown in FIG. 2.

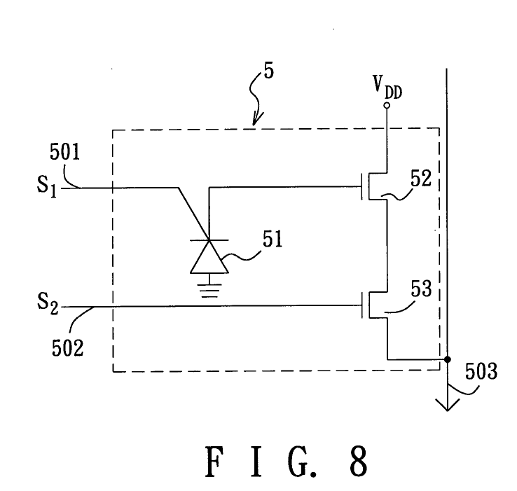

Referring to FIG. 8, the second preferred embodiment of an active pixel sensor 5 according to the present invention is shown to comprise a photosensitive element 51, a source follower transistor 52, and a row select transistor 53. Except for the use of a different component configuration for the photosensitive element 51, the arrangement of the source follower transistor 52 and the row select transistor 53, as well as the operations relevant to the reset signal (S₁) at the reset line 501, the row select signal (S₂) at the row line 502, and the output signal (Sₒᵤₜ) at the column line 503 are essentially similar to those of the previous embodiment described beforehand.

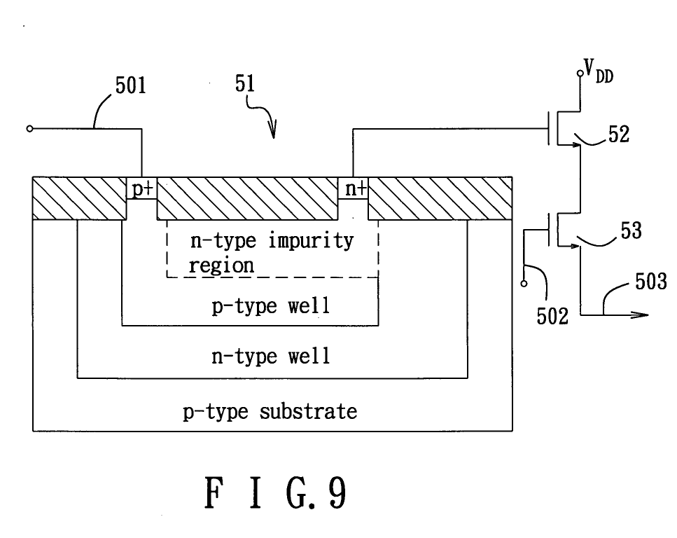

Referring to FIG. 9, the photosensitive element 51 is shown to have a triple-well PNPN configuration. Aside from minimizing cross-talk among pixel sensors, the depletion region formed at the internal PNPN junction permits an increase in the photon absorption efficiency, augments the light sensing ability of the photosensitive element 51, and increases the start_exposure voltage (V1) correspondingly, thereby increasing the image dynamic range for improving imaging sensitivity. It is noted that charging of the photosensitive element 51 can be simply conducted through one end of the PNPN configuration.

The following are some of the advantages of the active pixel sensors 2, 5 of this invention over the prior art:

1. In the active pixel sensor 2, the reset diode 22 is formed by providing a p-type well in the n-type impurity region of the photosensitive element 21. The resulting configuration is a PNP-type structure. Conduction of the integrated PN diode can easily result in the appropriate reverse bias voltage for the photodiode. As a result, the body effect associated with the various transistors of the conventional 3T and 4T active pixel sensors can be eliminated, the start_exposure voltage (V1) can be increased, and the image dynamic range can be increased as well, thereby improving the imaging sensitivity.

2. Since the reset diode 22 is used to replace a transistor, the KTC noise encountered during on/off transistor activity can be avoided.

3. Since the reset diode 22 is formed in the photosensitive element 21 in the active pixel sensor 2, while the active pixel sensor 5 only requires one photosensitive element 51, and since each of the active pixel sensors 2, 5 only utilizes two transistors 23, 24 and 52, 53, the light transmissibility per pixel unit area is far greater than those of the conventional 3T and 4T active pixel sensors. The light sensing area of the pixel sensors 2, 5 is effectively increased to greatly improve the imaging sensitivity.

4. The PN junction of the photosensitive element 21 is closer to the surface of the active pixel sensor 2 so as to improve sensitivity when sensing light with shorter wavelength, such as blue light.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An active pixel sensor comprising:
a photosensitive element for generating an electrical signal in response to detected light and for updating the electrical signal in response to a reset signal;
a first transistor, coupled electrically to said photosensitive element, for amplifying the electrical signal to result in an output signal; and
a second transistor coupled electrically to said first transistor and responsive to a row select signal for controlling output of the output signal.

2. The active pixel sensor as claimed in claim 1, wherein said photosensitive element is a photo diode having a triple-well PNPN configuration.

3. The active pixel sensor as claimed in claim 1, further comprising a reset diode for outputting the reset signal that is used to update the electrical signal of said photosensitive element.

4. The active pixel sensor as claimed in claim 3, wherein said reset diode is a photo diode.

5. The active pixel sensor as claimed in claim 3, wherein said photosensitive element is a semiconductor element having an n-type impurity region, said reset diode being formed by providing a p-type well in said n-type impurity region of said photosensitive element to result in a PNP-type structure.

6. An image sensing module comprising:
a plurality of active pixel sensors, each of which includes a photosensitive element, a first transistor, and a second transistor,
said photosensitive element being capable of generating an electrical signal in response to detected light, and updating the electrical signal in response to a reset signal,
said first transistor being coupled electrically to said photosensitive element and amplifying the electrical signal to result in an output signal,
said second transistor being coupled electrically to said first transistor and being responsive to a row select signal for controlling output of the output signal, said active pixel sensors being arranged in a rectangular array;
a plurality of reset lines, each of which is coupled to and shared by said active pixel sensors in a respective same row of the rectangular array for transmitting the reset signal to said active pixel sensors in the respective same row of the rectangular array;
a plurality of row lines, each of which is coupled to and shared by said active pixel sensors in a respective same row of the rectangular array for transmitting the row select signal to said second transistors of said active pixel sensors in the respective same row of the rectangular array; and
a plurality of column lines, each of which is coupled to and shared by said active pixel sensors in a respective same column of the rectangular array for transmission of the output signals from said second transistors of said active pixel sensors in the respective same column of the rectangular array.
